(19) United States
(12) Patent Application Publication
(10) Pub. No.: US 2016/0233117 A1
(43) Pub. Date: Aug. 11, 2016

(54) VERTICAL WAFER BOAT

(71) Applicant: CoorsTek KK, Tokyo (JP)

(72) Inventors: Shigeaki KUROI, Nishiokitama-gun (JP); Tomokazu KIMURA, Nishiokitama-gun (JP); Jianhui LI, Nishiokitama-gun (JP)

(73) Assignee: CoorsTek KK, Tokyo (JP)

(21) Appl. No.: 15/040,680

(22) Filed: Feb. 10, 2016

(30) Foreign Application Priority Data
Feb. 10, 2015 (JP) 2015-023744

(51) Int. Cl. H01L 21/673

(52) U.S. Cl. CPC H01L 21/67309

(57) ABSTRACT

Provided is a vertical wafer boat with columns having a rectangular cross section, and capable of making a flow of a film-forming gas between wafer support portions more uniform, suppressing variation in the film thickness in a wafer plane, and forming a more uniform film. A vertical wafer boat includes columns on which wafer support portions for mounting a plurality of wafers are formed, and a top plate and a bottom plate that fix upper and lower end portions of the columns. At least one of the columns includes two column portions and extending in an up and down direction and having a rectangular cross section, and a plurality of the wafer support portions that connects the two column portions and mounts wafers on upper surfaces.

### BACKGROUND OF THE INVENTION

1. Field of the Invention

The present invention relates to a vertical wafer boat, more particularly a vertical wafer boat in consideration of gas flows around wafer boat columns.

2. Description of the Related Art

Vertical wafer boats are widely employed in heat treatment processing equipment, for example, a vertical heat treatment furnace, in a semiconductor manufacturing process, such as chemical vapor deposition (CVD).

Typically, a vertical wafer boat includes a plurality of columns, for example, four columns, in which a plurality of wafer support portions is formed for mounting a plurality of wafers, to which film-forming treatment is to be applied, and a top plate and a bottom plate that fix upper and lower end portions of the columns.

Then, wafers are mounted on the respective wafer support portions of the vertical wafer boat, and the vertical wafer boat is accommodated in the vertical heat treatment furnace, so that predetermined heat treatment is performed.

In this heat treatment, a film-forming gas uniformly flows between the wafers, so that uniform films can be formed.

Incidentally, a cross-sectional shape of the column is typically a rectangular. For example, as disclosed in JP 2005-294509 A, a vertical wafer boat with columns having a C-shaped cross section has been proposed. Specific description will be given with reference to FIGS. 10 to 12.

As illustrated in FIGS. 10 and 11, a vertical wafer boat 10 includes insertion-side columns 11 and 11 having a C-shaped cross section, a depth-side column 12 having a rectangular cross section, and a top plate 13 and a bottom plate 14 that fix upper and lower end portions of the insertion-side columns 11 and the depth-side column 12.

Further, a plurality of wafer support portions 11a having a C-shaped cross section and having one end fixed to the column (the one end extending from a side surface of the column) is formed in the insertion-side column 11, and a plurality of wafer support portions 12a having a rectangular cross section is formed in the depth-side column 12.

Then, a wafer W is supported by the wafer support portions 11a of the wafer insertion-side columns 11 having a C-shaped cross section and the wafer support portion 12a of the depth-side column 12 having a rectangular cross section, and predetermined heat treatment is performed.

Further, in JP 2005-294509 A, as illustrated in FIG. 12, a wafer support portion 15a (depth-side column 15) having a C-shaped cross section, and having both ends fixed to the column is described.

Incidentally, when the cross section shape is a rectangular like the column 12 illustrated in FIG. 11, and a width T of the column 12 is large, a flow of a film-forming gas the wafer support portions becomes non-uniform, and formation of the uniform film is difficult. To be specific, there are technical problems that a film-forming thickness of a wafer surface near the column becomes thin, and variation in the film thickness in a wafer plane becomes large.

Meanwhile, when the width T of the column 12 is small, there are technical problems that support of the wafer becomes unstable, and mechanical strength of the vertical wafer boat becomes weak.

Further, with the wafer support portion 11a having a C-shaped cross section and having one end connected to the column 11, there are technical problems that the wafer is easily deformed downward due to the weight of the wafer, and cannot stably support the wafer.

Further, with the wafer support portion 15a having a C-shaped cross section and having both ends connected to the column 15, downward deformation of the wafer due to the self-weight of the wafer is suppressed. However, when a thickness t (see FIG. 12) of the wafer support portion is thin, there are technical problems that the mechanical strength of the column 15 against an external force from a cross direction is decreased, and a strong vertical wafer boat cannot be obtained.

Especially, in the wafer support portion 15a (column 15) having a C-shaped cross section, an inside of the column is curved, and thus flows of the film-forming gas intersect on the surface of the wafer. Therefore, there are technical problems that the flow of the film-forming gas near the column is substantially changed, and substantial variation in the film thickness of the wafer is caused.

Further, the flow of the film-forming gas is substantially changed. Therefore, there is a technical problem that finding out the best condition to make the variation in the film thickness small is difficult.

The present inventors have diligently studied with a view to the vertical wafer boat with columns having a rectangular cross section, having small change of the flow of the film-forming gas near the column, and with which the best condition to make the variation in the film thickness small can be easily found, and the inventors have completed the present invention.

### SUMMARY OF THE INVENTION

The present invention has been made in view of the above-described technical problems, and an objective is to provide a vertical wafer boat with columns having a rectangular cross section and capable of making a flow of a film-forming gas between wafer support portions more uniform, suppressing variation in the film thickness in a wafer plane, and forming a more uniform film.

A vertical wafer boat according to the present invention is a vertical wafer boat including columns in which wafer support portions for mounting a plurality of wafers are formed, and a top plate and a bottom plate that fix upper and lower end portions of the columns, at least one of the columns including two column portions extending in an up and down direction, and having a rectangular cross section, and a plurality of the wafer support portions that connects the two column portions and mounts the wafers on upper surfaces.

As described above, a gap (penetrating slit portion) is formed between the two column portions. Therefore, circulation of a film-forming gas becomes possible from a wafer support portion side to a back surface side of the column, or from the back surface side of the column to the wafer support portion side.

Therefore, the width of the column can be made smaller than that of a case where no gap (no penetrating slit portion) is formed, and an influence of the column on the flow of the film-forming gas can be made small. As a result, the flow of the film-forming gas between the wafer support portions can be made more uniform, the variation in the film thickness in a wafer plane can be suppressed, and a more uniform film can be formed.

Furthermore, the two column portions are connected by the support portion. Therefore, even if the two column portions are (have a small cross-sectional area), and mechanical strengths of the respective column portions is small, the strength of the column as a whole can be increased.

Here, a depth dimension of the support portion is desirably larger than a width direction of the support portion.

By making the depth dimension of the support portion larger than the width dimension of the support portion, an effect to increase the mechanical strength as a connecting member can be made large. In other words, when the depth dimension of the support portion is smaller than the width dimension of the column portion, the strength of the support portion is weak, and thus the effect to increase the mechanical strength as the connecting member is small.

Note that the support portion may be a support portion extending from the column portion in a horizontal direction, or a support portion including an inclined portion extending obliquely upward from the column portion, and a horizontal portion on which the wafer is mounted extending from a distal end of the inclined portion in the horizontal direction.

Further, facing surfaces of the two column portions are desirably planes parallel to each other.

As described above, the facing surfaces of the two column portions are made the planes parallel to each other. Therefore, the film-forming gas flowing between the two column portions becomes a flow in a radial direction of the wafer. Furthermore, the facing surfaces are not curved like the conventional C-shaped wafer support portion having both ends connected to a column. Therefore, intersection of the flows of the film-forming gas on the surface of the wafer can be suppressed. As a result, variation in the film thickness in a wafer plane can be suppressed, and a more uniform film can be formed.

According to the present invention, a vertical wafer boat with columns having a rectangular cross section, and capable of making a flow of a film-forming gas between wafer support portions more uniform, reducing variation in the film thickness on a wafer plane, and forming a more uniform film can be obtained.

### BRIEF DESCRIPTION OF THE DRAWING

FIG. 1 is a cross sectional view illustrating an embodiment of a vertical wafer boat according to the present invention;

FIG. 2 is a longitudinal sectional view illustrating an embodiment of the vertical wafer boat according to the present invention;

FIG. 3 is a cross sectional view illustrating one insertion-side column illustrated in FIG. 1;

FIG. 4 is a cross sectional view illustrating another insertion-side column illustrated in FIG. 1;

FIG. 5 is across sectional view illustrating a depth-side column illustrated in FIG. 1;

FIG. 6 is a cross sectional view illustrating a case in which a slit portion is not formed in the depth-side column illustrated in FIG. 5;

FIG. 7 is a perspective view of the depth-side column illustrated in FIG. 1 as viewed from a front surface side;

FIG. 8 is a perspective view of the depth-side column illustrated in FIG. 1 as viewed from a back surface side;

FIG. 9 is a longitudinal sectional view illustrating a modification of a support portion;

FIG. 10 is a perspective view of a conventional vertical wafer boat;

FIG. 11 is a cross sectional view of the vertical wafer boat illustrated in FIG. 10; and

FIG. 12 is a cross sectional view illustrating a conventional support portion.

### DESCRIPTION OF THE PREFERRED EMBODIMENTS

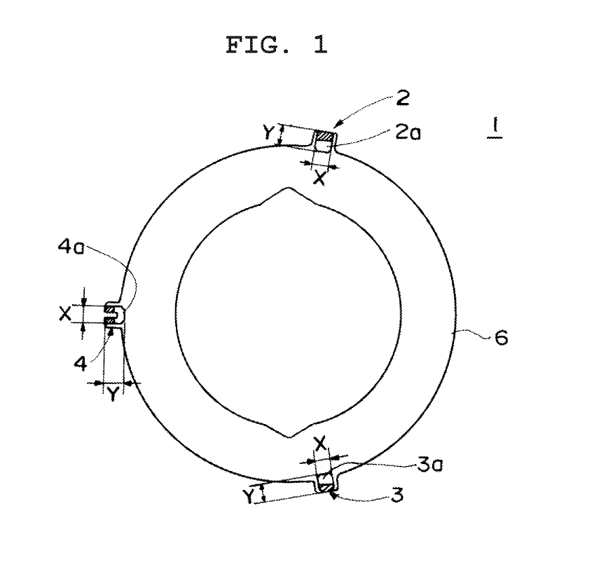

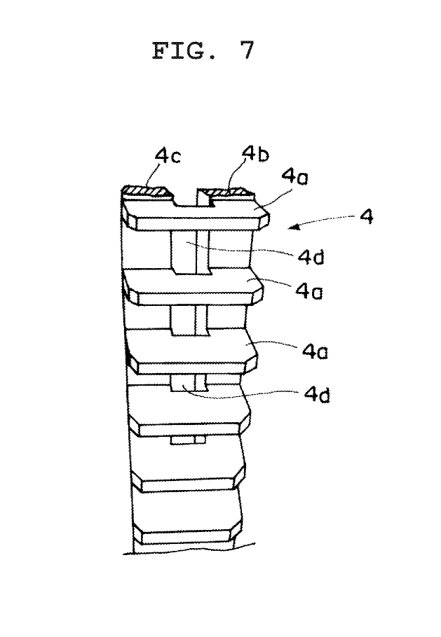

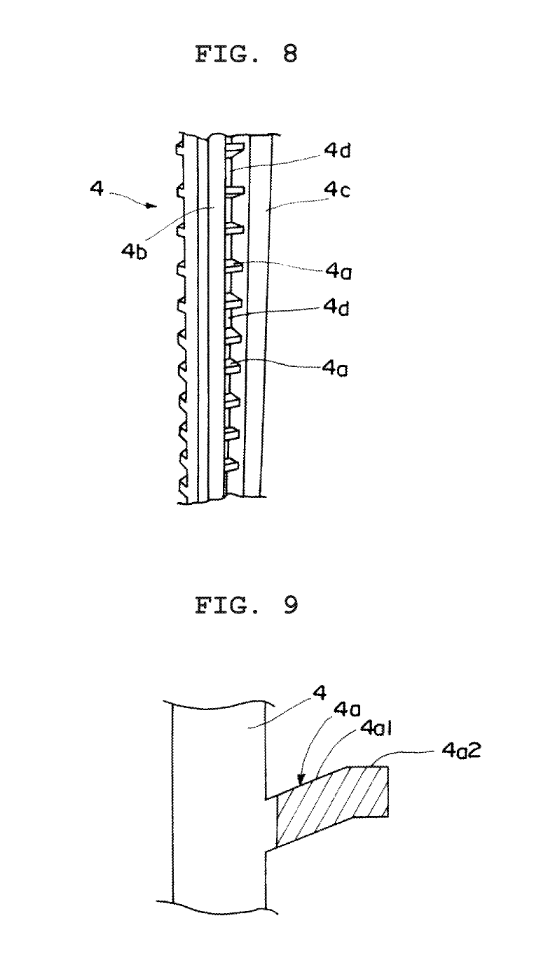

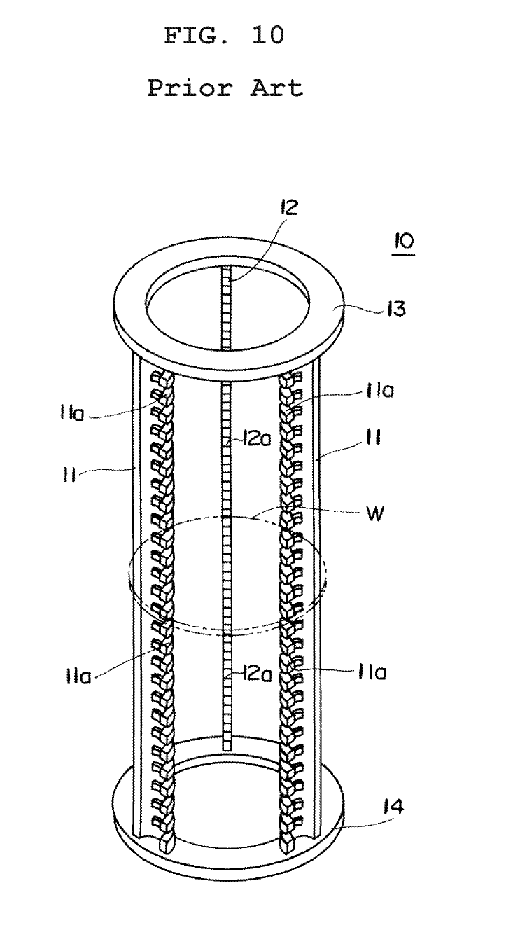

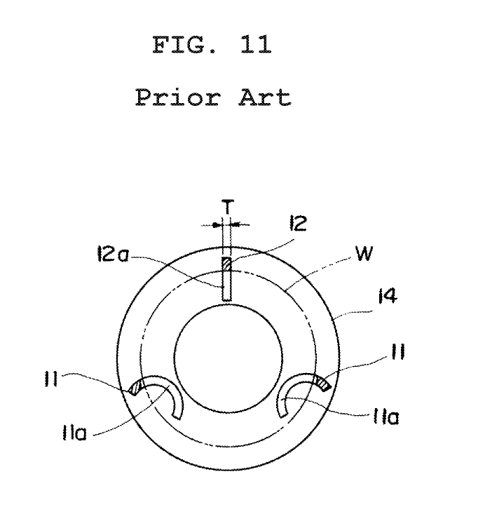

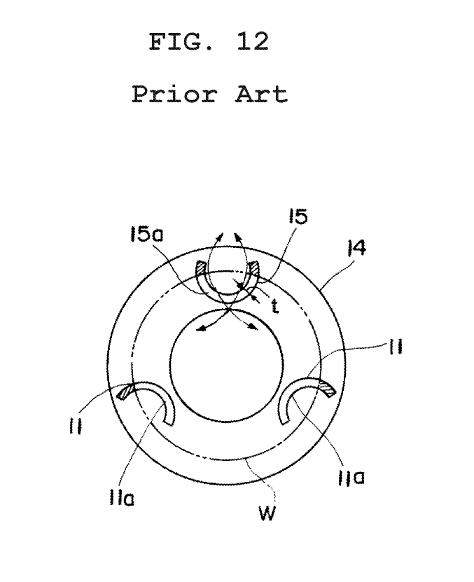

Hereinafter, a vertical wafer boat according to embodiments of the present invention will be described based on FIGS. 1 to 8.

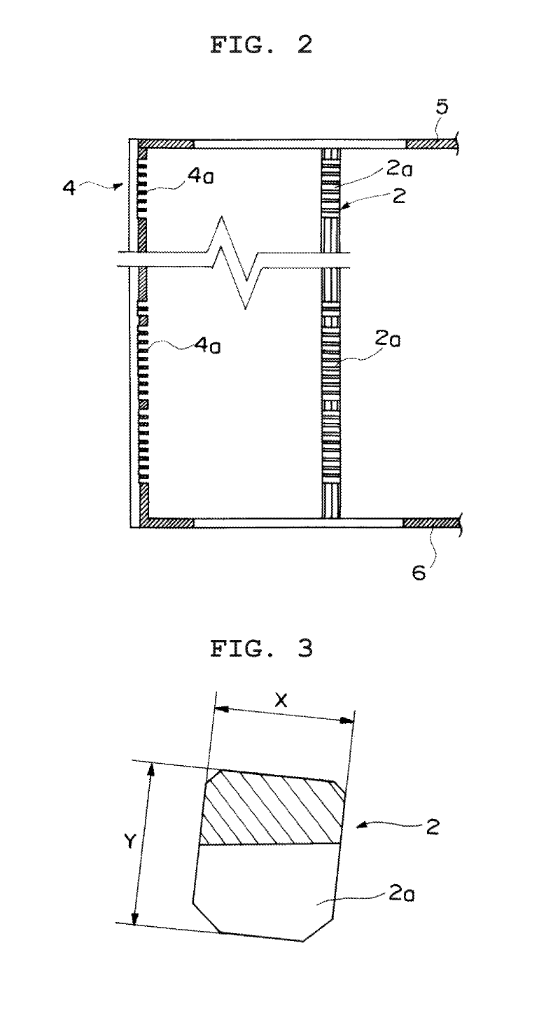

As illustrated in FIGS. 1 and 2, a vertical wafer boat 1 according to an embodiment of the present invention includes insertion-side columns 2 and 3 in which wafer support portions 2a and 3a for mounting a plurality of wafers are formed, a depth-side column 4 in which a wafer support portion 4a for mounting the plurality of wafers is formed, and a top plate 5 and a bottom plate 6 that fix upper and lower end portions of the columns.

As illustrated in FIG. 1, the insertion-side columns 2 and 3 and the depth-side column 4 are formed to have the same external dimensions. That is, width dimensions X of the insertion-side columns 2 and 3 and the depth-side column 4 are made the same, and depth dimensions Y of the insertion-side columns 2 and 3 and the depth-side column 4 are made the same.

Note that the insertion-side columns 2 and 3, the depth-side column 4, the top plate 5, and the bottom plate 6 that configure the vertical wafer boat 1 are formed of silicon carbide (SiC) material, for example.

In the insertion-side column 2, the cross section is formed into a rectangular shape, as illustrated in FIG. 3, and wafer support portions 2a for mounting a plurality of wafers are formed in an up and down direction. This wafer support portion 2a is formed by cutting a groove from one side surface of the insertion-side column 2 with a rotary cutting tool.

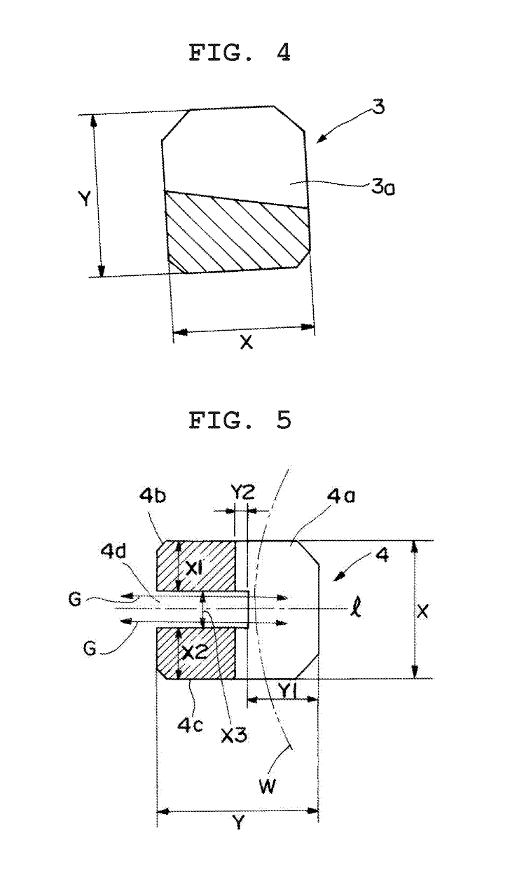

Similarly, in the insertion-side column 3, the cross section is formed into a rectangular shape, as illustrated in FIG. 4, and wafer support portions 3a for mounting the plurality of wafers are formed in the up and down direction. This wafer support portion 3a is formed by cutting a groove from one side surface of the insertion-side column 2 with a rotary cutting tool.

As illustrated in FIGS. 5, 7, and 8, the depth-side column 4 includes two column portions 4b and 4c extending in the up and down direction and having a rectangular cross section, and a plurality of wafer support portions 4a that connects the two column portions 4b and 4c and mounts the wafers on upper surfaces. The support portions 4a are extending from the column portions 4b and 4c of the depth-side column 4 in a horizontal direction toward a direction of a central portion of the vertical wafer boat 1.

Further, as illustrated in FIG. 5, a penetrating linear slit portion (gap) 4d extending from a back surface side to the wafer support portion 4a side is formed in the depth-side column 4. Further, the penetrating slit portion (gap) 4d is linearly extending in the up and down direction of the depth-side column 4.

Therefore, the depth-side column 4 is divided into the two column portions 4b and 4c by the slit portion 4d, and facing surfaces of the two column portions are formed into planes, and the planes are formed in parallel to each other.

Further, the slit portion 4d is desirably symmetrically arranged with respect to a central line 1, and width dimensions X1 and X2 of the two column portions 4b and 4c are desirably formed to be the same dimension. When the width dimensions X1 and X2 of the two column portions 4b and 4c are formed to be the same dimension, deviation is hard to occur in the film-forming gas flowing around the two column portions 4b and 4c, and as a result, a uniform flow can be achieved.

Further, a width dimension X3 of the slit portion (gap) 4d is desirably approximately the same dimension as the width dimensions X1 and X2 of the two column portions 4b and 4c. Making the width dimension X3 of the slit portion (gap) 4d extremely large and the width dimensions X1 and X2 of the column portions 4b and 4c extremely small is not preferable because the mechanical strength of the vertical wafer boat is lowered.

Note that the wafer support portion 4a is formed by cutting a groove from one side surface (front surface side) of the depth-side column 4 with a rotary cutting tool. Further, the slit portion 4d is formed by cutting a groove from a back surface side of the depth-side column 4 with a rotary cutting tool.

As described above, the penetrating slit portion (gap) 4d is formed, and thus circulation of a film-forming gas G becomes possible from the wafer support portion 4a side to the back surface side of the depth-side column 4, or from the back surface side of the depth-side column 4 to the wafer support portion 4a side, as illustrated in FIG. 5.

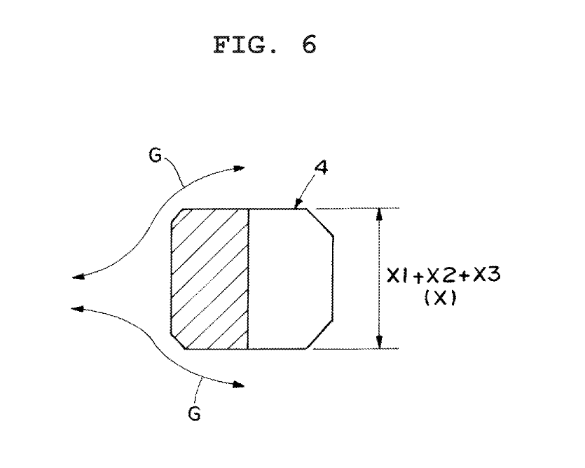

Therefore, the width dimension (X1 and X2) of the column 4 illustrated in FIG. 5 can be made smaller than a width dimension X1 +X2 +X3 of the column portion in the case where no penetrating slit portion 4d is formed, as illustrated in FIG. 6. Consequently, an influence by the column on the flow of the film-forming gas G can be reduced.

Furthermore, the slit portion (gap) 4d is linearly formed, and the facing surfaces of the two column portions 4b and 4c are formed into the parallel planes. Therefore, as illustrated in FIG. 5, the film-forming gas G flowing through the slit portion 4d linearly flows, and turbulence of the flow is suppressed.

As a result, the flow of the film-forming gas between the wafer support portions can be made more uniform, the variation in the film thickness on a wafer plane can be suppressed, and a more uniform film can be formed.

Further, as illustrated in FIG. 5, the slit portion (gap) 4d is extending in the support portion 4a (enters the support portion 4a). However, the slit portion 4d is not formed in a region where the wafer W is actually placed.

If the slit portion 4d is formed in the portion (region) where the wafer W is actually placed, the film is formed on the back surface of the wafer W. Consequently, particles may be generated when the wafer W is conveyed out from the wafer support portion 4a.

Thus, an amount Y2 of extending into the support portion 4a (an entering dimension) of the slit portion (gap) 4d is preferably as small as possible.

Further, in the depth-side column 4, the two column portions 4b and 4c are connected with the support portion 4a. Since these two column portions 4b and 4c are connected with the support portion 4a, even if the two column portions 4b and 4c are thin (the cross-sectional areas are small), and the mechanical strengths of the respective column portions are low, the strength of the column as a whole can be high.

Further, the depth dimension Y1 of the support portion 4a is desirably larger than the width dimensions X1 and X2 of the column portions 4b and 4c.

If the depth dimension Y1 of the support portion 4a is smaller than the width dimensions X1 and X2 of the column portions 4b and 4c, the strength of the support portion 4a is low, and an effect to increase the mechanical strength as the connecting member is small.

Note that, in the above embodiment, a case of applying the present invention only to the depth-side column 4 has been described. However, the present invention may be applicable to all of the columns of the vertical wafer boat.

Further, in the above embodiment, a vertical wafer boat having three columns has been exemplarily described. The number of columns, however, can be appropriately changed.

Further, in the above embodiment, a case where the external dimensions of the insertion-side columns 2 and 3 and the depth-side column 4 are to the same has been described. However, the width dimension X (of the support portion) of at least one column of the insertion-side columns 2 and 3 may be changed to become shorter than the depth dimension Y of the support portion of the column.

Further, in the above embodiment, the support portion 4a extending from the column portions 4b and 4c of the depth-side column 4 in the horizontal direction has been described. However, as illustrated in FIG. 9, a support portion 4a having an inclined portion 4a1 extending obliquely upward from the column portions 4b and 4c, and a horizontal portion 4a2 extending from a distal end of the inclined portion 4a1 in the horizontal direction may be employed. In that case the wafer is held by the horizontal portion 4a2.

1. A vertical wafer boat comprising:
columns in which wafer support portions for mounting a plurality of wafers are formed; and
a top plate and a bottom plate that fix upper and lower end portions of the columns,
at least one of the columns including
two column portions extending in an up and down direction, and having a rectangular cross section, and
a plurality of the wafer support portions that connect the two column portions and mount the wafers on upper surfaces.

2. The vertical wafer boat according to claim 1, wherein a depth dimension of the support portion is larger than a width direction of the support portion.

3. The vertical wafer boat according to claim 1, wherein the support portion includes an inclined portion extending obliquely upward from the column portion, and a horizontal portion extending in a horizontal direction from a distal end of the inclined portion, and on which the wafer is mounted.

4. The vertical wafer boat according to claim 1, wherein facing surfaces of the two column portions are planes parallel to each other.

5. The vertical wafer boat according to claim 2, wherein facing surfaces of the two column portions are planes parallel to each other.

6. The vertical wafer boat according to claim 3, wherein facing surfaces of the two column portions are planes parallel to each other.
